(19) United States
(12) Patent Application Publication
(10) Pub. No.: US 2012/0091542 A1
(43) Pub. Date: Apr. 19, 2012

(54) METHODS FOR THE DEPOSITION OF TERNARY OXIDE GATE DIELECTRICS AND STRUCTURES FORMED THEREBY

(76) Inventors: Mark R. Brazier, Hillsboro, OR (US); Matthew V. Metz, Hillsboro, OR (US); Michael L. McSwiney, Scappoose, OR (US); Markus Kuhn, Portland, OR (US); Michael L. Hattendorf, Beaverton, OR (US)

(21) Appl. No.: 13/330,569

(22) Filed: Dec. 19, 2011

Related U.S. Application Data
(62) Division of application No. 11/864,831, filed on Sep. 28, 2007, now abandoned.

(51) Int. Cl. H01L 29/78

(52) U.S. Cl. 257/411; 257/E29.255

(57) ABSTRACT

Methods and associated structures of forming a microelectronic device are described. Those methods may include introducing a first metal source, a second metal source and an oxygen source into a chamber and then forming a ternary oxide film comprising a first percentage of the first metal, a second percentage of the second metal, and a third percentage of oxygen.

### CROSS REFERENCE TO RELATED APPLICATIONS

This application is a divisional of U.S. patent application Ser. No. 11/864,831, filed Sep. 28, 2007, entitled “METHODS FOR THE DEPOSITION OF TERNARY OXIDE GATE DIELECTRICS AND STRUCTURES FORMED THEREBY.” This application is incorporated by reference herein in its entirety.

### BACKGROUND OF THE INVENTION

Transistors are well known in the art. Transistors are the building blocks of all integrated circuits. Modern integrated circuits interconnect literally millions of transistors together to perform a wide variety of functions. The performance and reliability of a specific integrated circuit is directly related to the performance and reliability of the transistors of which it is comprised. Thus, in order to provide better performing integrated circuits in the future, one needs to improve the electrical characteristics of transistors, such as by improving the electrical/chemical properties of high k gate dielectrics utilized in such transistors.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1i represent structures according to an embodiment of the present invention.

FIGS. 2a-2b represent flow charts according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may include introducing a first metal source, a second metal source and an oxygen source into a chamber and then forming a ternary oxide film comprising a first percentage of the first metal, a second percentage of the second metal, and a third percentage of oxygen. Embodiments of the present invention enable the modification and optimization of the chemical composition, energy band structure, and associated electrical properties of ternary high k gate oxides. Specific electrical parameters that can be optimized using the embodiments in this invention include positive bias temp instability.

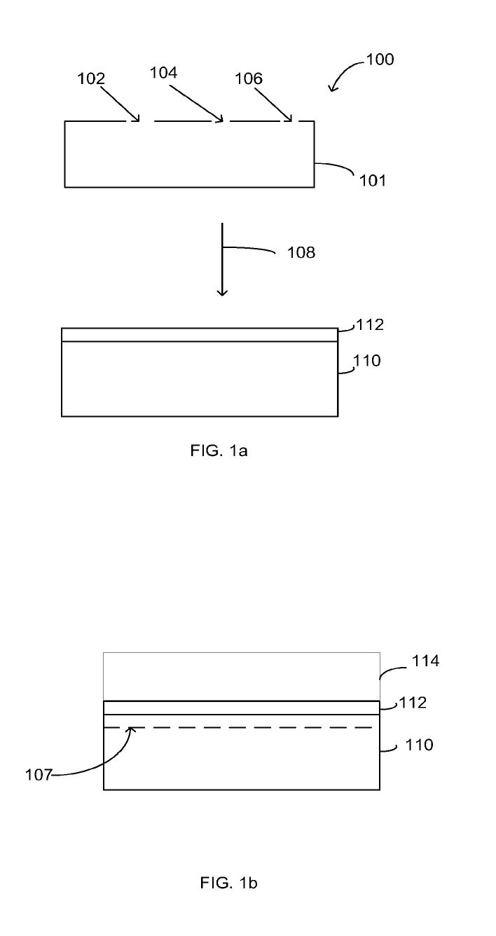

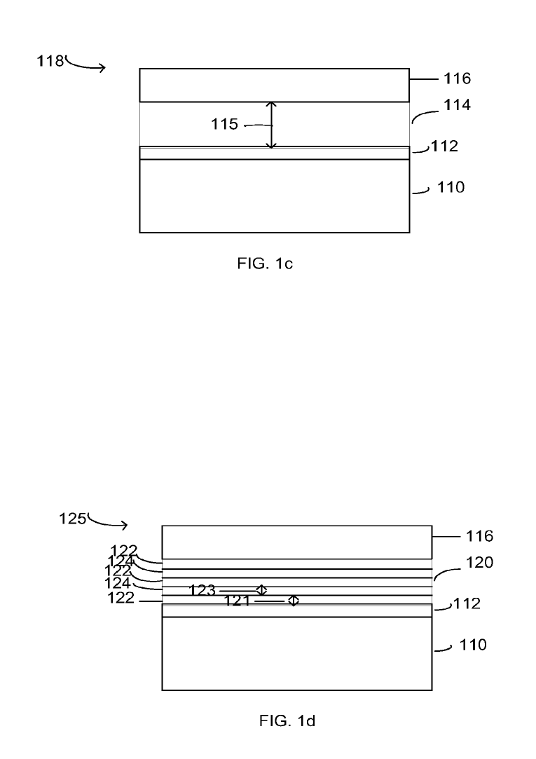

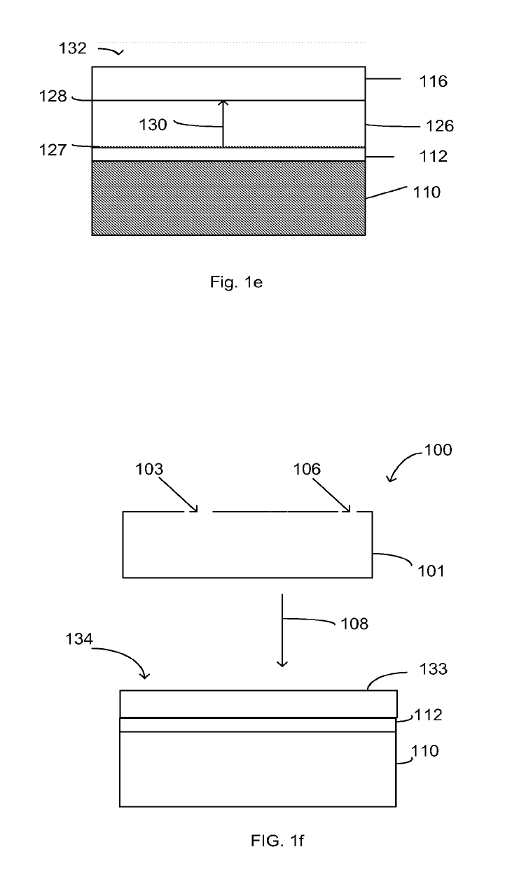

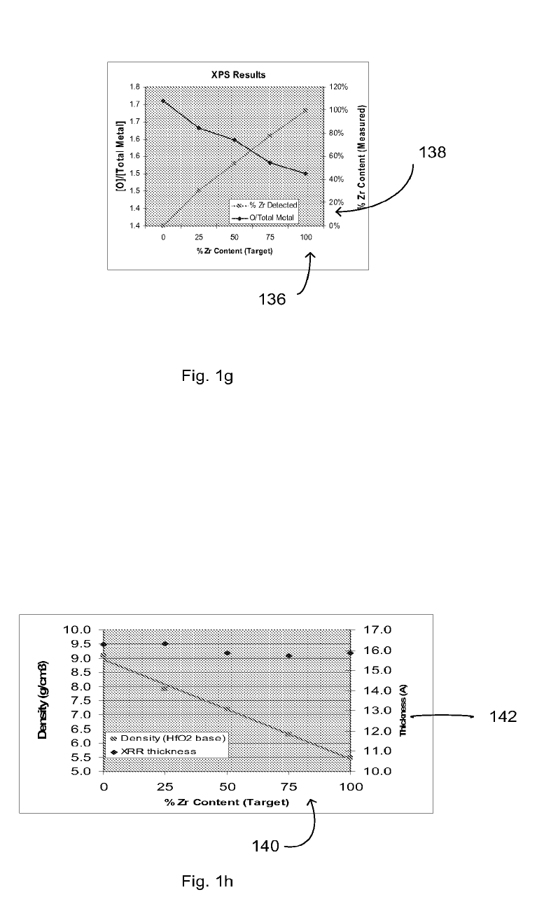

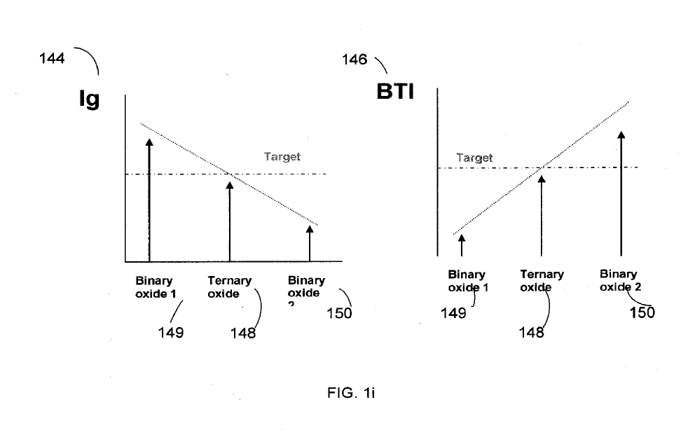

FIGS. 1a-1f illustrate an embodiment of a method of forming a microelectronic structure, such as a transistor structure, for example. FIG. 1a illustrates a cross-section of a portion of a chamber system 100. The chamber system may comprise a deposition system. The chamber system 100 may comprise a deposition chamber 101, such as but not limited to an atomic layer deposition (ALD) chamber 101, as is known in the art. In one embodiment, the chamber system 100 may further comprise a first metal source inlet 102, a second metal source inlet 104 and an oxygen source inlet 106, that may introduce a first metal source, a second metal source and a oxygen source into the chamber 101 respectively.

In embodiment one, the two separate metal source inlets 102, 104 may be comprise two separate ampoules or other such vessels, that may be attached to the chamber 101, along with other reactants as necessary according to the particular application. The first and second metal sources for the two source inlets 102, 104 may comprise precursors for the formation of a ternary oxide film. The precursor choice may vary by element of interest. For example, when the precursor comprises hafnium, the ampoule may contain a precursor which includes (but is not limited to) hafnium chloride, hafnium amides, hafnium alkoxides and combinations thereof. For lanthanides and Yttrium precursors, choices include (but are not limited to) Tris(2,2,6,6-tetramethyl-3,5-heptadionato)-lanthanum [La(THD)₃], Tris(6-ethyl-2,2-dimethyl-3,5-decane-dionato)-lanthanum [La(EDMDD)₃], and tris(alkylcyclopentadienyl)lanthanum (where alkyl includes, but is not limited to methyl, ethyl, sec-butyl, and iso-propyl).

Zirconium precursors include (but are not limited to) zirconium chloride, zirconium amides, zirconium alkoxides. Silicon precursors include (but are not limited to) silicon tetrachloride, tetrakis(dimethylamino)silicon, and hexamethyldisilazane. Titanium precursors include, but are not limited to chlorides and amines similar to those found for silicon. Tantalum precursors include, but are not limited to, Pentakis(dimethylamido)tantalum, Trisdimethylamine, NN′dimethylethylenediamine-Ta(V), Tert-butylimido tris(diethylamido)tantalum, tantalum alkoxides and Tert-amylimido tris-(dimethylamido)tantalum. Common aluminum precursors include, but are not limited to, tri-methyl aluminum, alane and substituted alanes.

The oxygen source inlet 106 may provide an oxygen source into the deposition chamber 101, wherein the oxygen source may comprise oxidizers such materials as but not limited to water, oxygen, ozone, and combinations thereof. In one embodiment, the various precursors materials and oxidizer sources utilized can be viewed as belonging to the phase diagram X—Y—O, where O is oxygen, and X and Y include, but are not limited to, hafnium, zirconium, silicon, aluminum, yttrium, all lanthanides, titanium and tantalum and combinations thereof.

In general, the formation of several types of ternary oxide films may be accomplished according to the embodiments of the present invention. The various ternary oxide films that may be formed may include but are not limited to a ternary oxide, a mixed ternary oxide, a nano-laminate ternary oxide film, and/or a film with a gradient composition. In one embodiment, a mixed ternary oxide film 114 (FIG. 1b) may be formed on a substrate 110, that may be comprised of materials such as, but not limited to, silicon, silicon-on-insulator, germanium, indium antimonide, lead telluride, indium arsenide, indium phosphide, gallium arsenide, gallium antimonide, or combinations thereof.

A silicon layer 112 may be optionally disposed on a channel region 107 of the substrate 110. In one embodiment, the substrate 110 may include various devices (not shown) that, together, form a microprocessor. In one embodiment, the mixed ternary oxide film 114 may be used as a gate dielectric film in a transistor structure. In an embodiment, the substrate 110 may include devices that together form multiple microprocessor cores on a single die.

In one embodiment, the mixed ternary oxide film 114 may be formed by utilizing an ALD deposition process 108 (referring back to FIG. 1a). In one embodiment, the two precursor sources (as delivered by the first and second source inlets 102, 104 into the ALD chamber 101) can be pulsed alternately or at the same time—for example, in one embodiment, one pulsing scheme may comprise pulsing the first and second source substantially simultaneously, followed by pulsing the oxygen source (delivered by the oxidizer source inlet 106).

In another embodiment, the first and second metal sources may be pulsed separately, followed by pulsing the oxygen source. In one embodiment, the mixed ternary oxide film 114 may comprise a portion of a transistor structure 118 that may comprise a metal gate 116, and wherein the mixed ternary oxide film 114 may comprise a high-K gate dielectric film (FIG. 1c). In one embodiment, the mixed ternary oxide film 114 may comprise a first percentage of the first metal, a second percentage of the second metal, and a third percentage of oxygen.

In one embodiment, one of the first and second percentages of the mixed ternary oxide 114 may comprise from about 1 percent to about 99 percent of the composition of the mixed ternary oxide 114. In one embodiment, the metal gate 116 may be disposed on the mixed ternary oxide 114, wherein the structure 118 may comprise a portion of a metal gate transistor.

In one embodiment, a thickness 115 of the mixed ternary oxide 114 may comprise about 30 angstroms and below. The mixed ternary oxide 114 may comprise a high K gate oxide comprising a mixture of a first binary oxide and a second binary oxide. In one embodiment, the first binary oxide and the second binary oxide may comprise an oxide of one of hafnium, zirconium, silicon, aluminum, yttrium, all lanthanides, titanium and tantalum and combinations thereof.

In another embodiment, a nanolaminate film 120 may be formed on the substrate 110 (FIG. 1d). In one embodiment, a series of alternating first metal source pulses and then oxidizer pulses may be performed during an ALD process, followed by a series of alternating second metal source pulses and then oxidizer pulses may be performed to form the desired nanolaminate film 120.

For example, in one embodiment, a series of alternating hafnium pulses and then oxidizer pulses may be performed during an ALD process, followed by a series of alternating zirconium pulses and then oxidizer pulses to form the nanolaminate film 120. The desired final composition and pulse sequence of the reactants will vary depending upon the particular application. The nanolaminate film 120 may comprise alternating layers of a first binary oxide 122 and a second binary oxide 124 stacked upon one another.

In one embodiment, the first binary oxide 122 and the second binary oxide 124 may each comprise an oxide comprising a first metal and a second metal respectively. In one embodiment, the first and second metal may comprise one of hafnium, zirconium, silicon, aluminum, yttrium, all lanthanides, titanium and tantalum and combinations thereof. The first and second binary oxides 122, 124 may comprise thicknesses 121 and 123 respectively, which may comprise 2-5 angstroms in some embodiments, but will vary according to the particular application. In one embodiment, the nanocomposite oxide 120 may comprise a high K gate oxide of a transistor structure 125.

In another embodiment, a graded ternary oxide film 126 may be formed on the substrate 110 (FIG. 1e). In one embodiment, the graded ternary oxide film 126 may be formed by varying a ratio of the first metal source to the second metal source by varying the pulses during an ALD process from a bottom portion 127 of the graded ternary oxide film 128 film to a top portion 128 of the graded ternary oxide film 128 (i.e., by varying the pulses of the first and metal sources from the beginning to the end of the deposition time).

In this manner, a graded ternary oxide film 126 may be formed in which the concentration of the first metal and the second metal (and thus the concentration of the first binary oxide and the second binary) may vary from the bottom portion 127 of the graded ternary oxide film 126 to the top portion 128 of the graded ternary oxide film 126 to create a film of variable composition comprising a concentration gradient 130. In one embodiment, the graded ternary oxide film 126 may comprise a high K gate oxide of a transistor structure 132. In one embodiment, the graded ternary oxide 126 (that may comprise a gate oxide) may comprises a concentration gradient 130 in the percentage of the first binary oxide throughout a thickness of the graded ternary oxide 126 (gate oxide).

In another embodiment, the chamber system 100 may comprise a single mixed precursor source inlet 103 along with the oxygen source inlet 106 to form a ternary oxide film 133 utilizing the ALD process 8 (FIG. 1f). The single mixed precursor source 103 may receive a mixture of the first metal and the second metal to introduce into the chamber 101. The precursors include, but are not limited to, those previously described in the various embodiments of the present invention. In one embodiment, miscible liquid precursors may be used, wherein the two metal precursors may be mixed to achieve a molar ratio target for the final composition of the ternary oxide film. In one embodiment, the mixture of the first and second metals may be delivered to the chamber 101 via a vaporizer apparatus.

In another embodiment, when solid precursors are used, they can be dissolved in an appropriate solvent and delivered to the chamber 101 via a vaporizer apparatus as well. For liquid/solid precursor mixtures, a similar scheme may used. If the solid precursor is soluble in the liquid precursor, the two may be dissolved to obtain the correct molar ratio. Otherwise the two precursors may be mixed in an appropriate solvent. For a two solid precursor system, the two precursors can be dissolved in an appropriate solvent.

In the case if direct liquid injection (DLI) when a vaporizer may not available, then two precursors (liquid or solid) can be mixed to form a film of desired composition and the vapor in the headspace of the ampoule flushed to the chamber. When mixing precursors, it is possible to deposit a film of desired composition even when the vapor pressure of the precursors is not matched.

In this embodiment a mixed ternary oxide film 133 may be formed on the substrate 110 through alternating precursor and oxidizer pulses with each other. For example, a HfO₂/ZrO₂ film composition may be varied in a range from a molar 5% to 95% hafnium with the remaining film comprising zirconium. In this manner, a high K gate dielectric may be formed on the substrate 110 that may form a portion of a transistor structure 134. In one embodiment, a thickness of the mixed ternary oxide 133 may comprise about 30 angstroms and below. The mixed ternary oxide 133 may comprise a mixture of a first binary oxide and a second binary oxide. In one embodiment, the first binary oxide and the second binary oxide may comprise an oxide of one of hafnium, zirconium, silicon, aluminum, yttrium, all lanthanides, titanium and tantalum and combinations thereof.

FIG. 1g depicts mixed ternary oxide films with varying Zr/(Zr+Hf) that were deposited by atomic layer deposition and alternating the Zr- or Hf-precursor pulses in specific ratios. Target film compositions 136 of Zr/(Zr+Hf)=(0, 0.25, 0.5, 0.75, 1) are shown—referred to as % Zr content (target) on the x-axis. Film oxygen content, [O]/[total metal], as measured by XPS is shown on the left axis. There is a decrease in [O]/[total metal] with increasing Zr content. The film compositions, referred to as % Zr content (Measured) 138, as measured by XPS (X-ray photoelectron spectroscopy) are shown on the right axis. The measured Zr content is well matched to targeted Zr content. Thus, the methods of the present invention enable a basically 1:1 ratio between a target metal composition and a measured metal composition.

FIG. 1h shows mixed ternary oxide films with varying Zr/(Zr+Hf) that were deposited by atomic layer deposition and alternating the Zr- or Hf-precursor pulses in specific ratios. Target film compositions of Zr/(Zr+Hf)=(0, 0.25, 0.5, 0.75, 1) are shown—referred to as % Zr content (target) 140 on the x-axis. Mass density, as measured by XRR, is shown on the left axis. The mass density decreases as predicted by the relative mass of Zr vs. Hf and their relative concentrations in the film. The film thicknesses 142, referred to as % Zr content (Measured), as measured by XRR(X-ray reflectometry) are shown on the right axis. Thus, for embodiments of the present invention, ternary oxide thickness is substantially equivalent across a range of metal concentration, and therefore the film density tracks with respect to the quality of film, i.e. the film density tracks with the relative mass and concentration ratio of Hf and Zr.

Different metal oxides that can be used as high-K dielectrics for MOS technologies may have different electrical properties due to their chemical composition, defect density, and energy band structure. By mixing different metals into a single dielectric film using the methods described herein, the chemical composition, energy band structure, and associated electrical properties can be continuously modified to an optimum point.

For example, specific electrical parameters that can be optimized using the methods described in this invention may include, but are not limited to, gate leakage (Ig) and positive bias temp instability (BTI). FIG. 1i depicts an example wherein by mixing binary oxides (such as HfO2 and ZrO2, for example) to form a ternary oxide gate dielectric 148 prepared according to embodiments of the present invention, devices utilizing the gate dielectrics of the present invention may be optimize for both Ig 144 and BTI 146. Non-mixed (prior art) gate dielectrics that may comprise a single binary oxide (binary oxide 1 or binary oxide 2) may not be optimized to achieve the target BTI and/or Ig values. In one embodiment, a BTI may be optimized to a value below those obtained for gate dielectrics comprising silicon dioxide.

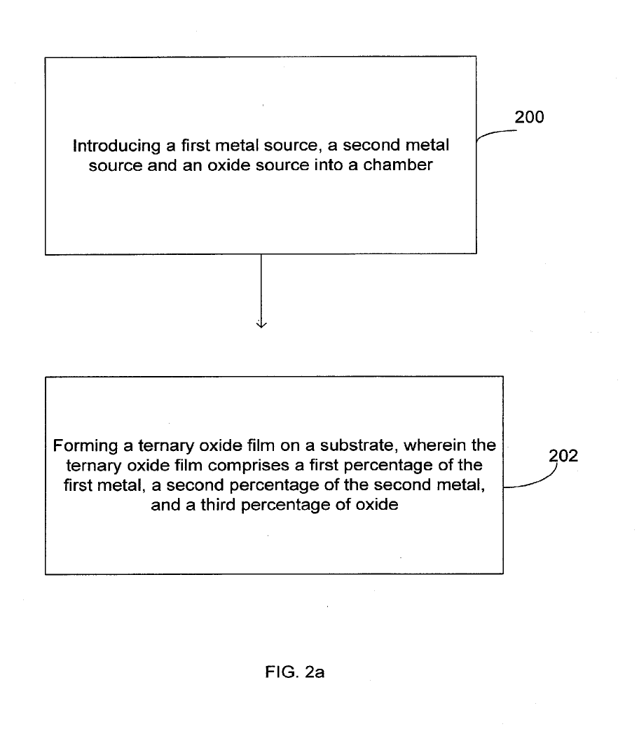

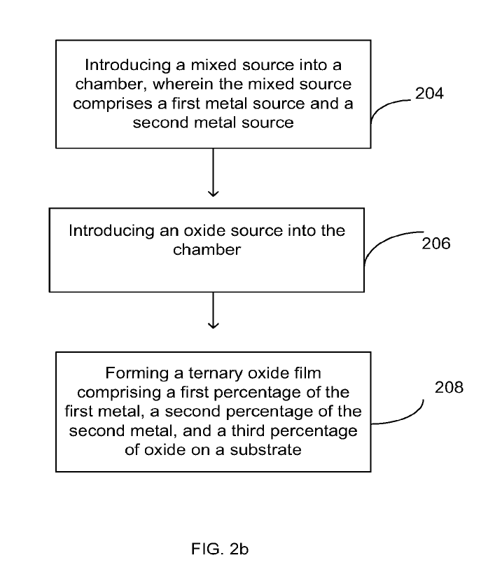

FIG. 2a-2b depict flow charts according to embodiments of the present invention. At step 200, a first metal source, a second metal source and an oxygen source are introduced into a chamber (FIG. 2a). At step 202, a ternary oxide film is formed on a substrate, wherein the ternary oxide film comprises a first percentage of the first metal, a second percentage of the second metal, and a third percentage of oxygen. At step 204, a mixed source is introduced into a chamber, wherein the mixed source comprises a first metal source and a second metal source (FIG. 2b). At step 206, an oxygen source is introduced into the chamber. At step 208, a ternary oxide film comprising a first percentage of the first metal, a second percentage of the second metal, and a third percentage of oxygen is formed on a substrate.

Benefits of the embodiments of the present invention enable the fabrication of microelectronic devices utilizing transistors employing ternary oxide gate dielectrics, such as hafnium oxide/zirconium oxide gate dielectrics, for example. Such ternary oxide gate dielectrics can achieve lower gate leakage (Ig) than those with silicon dioxide gate dielectrics at the same performance, and they may greatly improve reliability problems, such as bias Temperature Instability (BTI) in particular.

The fundamental electrical/chemical properties of conventional binary dielectrics may typically be modified in post processing steps (example post nitridation of SiO2). For example transistors using HfO2 gate dielectrics can achieve lower gate leakage (Ig) than those using SiO2 gate dielectrics at the same performance, but they suffer from reliability problems, such as Bias Temperature Instability (BTI) in particular. The reliability problems associated with HfO2 gate dielectrics, for example, have not been solved using post processing modification.

Embodiments of the present invention enable the modification and optimization of the chemical composition, energy band structure, and associated electrical properties of ternary high k gate oxides. Specific electrical parameters that can be optimized using the embodiments in this invention include gate leakage and positive bias temp instability. Different metal oxides that can be used as High-K dielectrics for MOS technologies have different electrical properties due to their chemical composition, defect density, and energy band structure.

By mixing different metals into a single dielectric film using the methods described herein, the chemical composition, energy band structure, and associated electrical properties can be continuously modified to an optimum point. This embodiments of the present invention include the deposition of several types of ternary mixed metal oxide films using atomic layer deposition (ALD), and the deposition of specific films for use as a gate dielectric.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic structures are well known in the art. Therefore, it is appreciated that the Figures provided herein illustrate only portions of an exemplary microelectronic structures that pertains to the practice of the present invention. Thus the present invention is not limited to the structures described herein.

What is claimed is:

1. A structure comprising:
a gate oxide comprising a first binary oxide and a second binary oxide, wherein the first binary oxide and the second binary oxide comprise a first metal and a second metal.

2. The structure of claim 1 wherein the first metal and the second metal comprise at least one of Hf, Zr, Si, Al, Y, a lanthanide Ti, and Ta.

3. The structure of claim 1 wherein the gate oxide comprises a mixture of the first binary oxide and the second binary oxide.

4. The structure of claim 1 wherein the thickness of the gate oxide comprises below about 30 angstroms.

5. The structure of claim 1 wherein the gate oxide is disposed on a silicon dioxide layer and a metal gate is disposed on the gate oxide, and wherein the gate oxide comprises a high k gate oxide, and wherein the silicon dioxide layer is disposed on a channel region of a transistor structure.

6. The structure of claim 1 wherein a percentage of the first metal may comprise about 1 percent to about 99 percent, and wherein the gate oxide comprises a concentration gradient in the percentage of the first binary oxide throughout a thickness of the gate oxide.

7. The structure of claim 1 wherein the gate oxide comprises a concentration gradient in the percentage of the first binary oxide throughout a thickness of the gate oxide.

8. A structure comprising:
a gate oxide comprising a first binary oxide and second binary oxide, wherein the first binary oxide and the second binary oxide comprise a first metal and a second metal, and wherein at least one layer each of the first binary oxide and the second binary oxide are alternately stacked upon one another.

9. The structure of claim 8 wherein the thickness of the at least one layer of the first and second binary oxides comprise about 3 to about 30 angstroms.

10. The structure of claim 8 wherein the gate oxide is disposed on a silicon dioxide layer and a metal gate is disposed on the gate oxide, and, wherein the gate oxide comprises a high k gate oxide, and wherein the silicon dioxide layer is disposed on a channel region of a transistor structure.

11. The structure of claim 8 wherein the first metal and the second metal comprise at least one of Hf, Zr, Si, Al, Y, a lanthanide, Ti, and Ta.
